(19) United States
(12) Patent Application Publication
(10) Pub. No.: US 2018/0320670 A1
(43) Pub. Date: Nov. 8, 2018

(54) ACTUATOR DEVICE AND METHOD FOR DRIVING THE SAME

(71) Applicant: Panasonic Intellectual Property Management Co., Ltd., Osaka (JP)

(72) Inventors: YURIKO KANEKO, Nara (JP); MAKI HIRAOKA, Nara (JP); KUNIHIKO NAKAMURA, Osaka (JP)

(21) Appl. No.: 16/038,809

(22) Filed: Jul. 18, 2018

Related U.S. Application Data
(63) Continuation of application No. PCT/JP2017/046074, filed on Dec. 22, 2017.

(30) Foreign Application Priority Data
Jan. 24, 2017 (JP) 2017-010630

(51) Int. Cl. F03G 7/00; H01L 41/04; H01L 41/09

(52) U.S. Cl. CPC F03G 7/005; H01L 41/18; H01L 41/092; H01L 41/042

(57) ABSTRACT

The actuator device according to the present invention comprises an actuator and an AC power supply capable of applying a high-frequency voltage to the actuator. The actuator comprises a flexible tube formed of a polymer, an inner electrode, and an outer electrode. In a cross section perpendicular to a longitudinal direction of the flexible tube, the inner electrode is in contact with at least a part of an inner periphery of the flexible tube. In the cross section, a part of an outer periphery of the flexible tube is coated with the outer electrode. In operation, the AC power supply applies a high-frequency voltage having a frequency of not less than 1 MHz to the actuator to deform the actuator in a direction from the inner electrode toward the outer electrode in the cross section. The AC power supply stops the application of the high-frequency voltage to the actuator to return the actuator to the original position thereof.

### CROSS-REFERENCES TO RELATED APPLICATIONS

This is a continuation of International Application No. PCT/JP2017/046074, with an international filing date of Dec. 22, 2017, which claims priority of Japanese Patent Application No. 2017-010630, filed on Jan. 24, 2017, the contents of which are hereby incorporated by reference.

### BACKGROUND

### 1. Technical Field

The present invention relates to an actuator device and a method for driving the same.

### 2. Description of the Related Art

Patent Literature 1 discloses a piezoelectric actuator. Patent Literature 2 discloses a tubular piezoelectric actuator. Patent Literature 3 discloses a functional element, a device employing the same, and a method for manufacturing the same.

### CITATION LIST

Patent Literature 1

Japanese patent laid-open publication No. 2001-197758A

Patent Literature 2

Japanese patent laid-open publication No. 2002-125383A

Patent Literature 3

Japanese patent laid-open publication No. 2004-281711A

### SUMMARY

An object of the present invention is to provide a novel actuator device and a method for driving the same.

The actuator device according to the present invention comprises an actuator and an AC power supply capable of applying a high-frequency voltage to the actuator. The actuator comprises a flexible tube formed of a polymer, an inner electrode, and an outer electrode. In a cross section perpendicular to a longitudinal direction of the flexible tube, the inner electrode is in contact with at least a part of an inner periphery of the flexible tube. In the cross section, a part of an outer periphery of the flexible tube is coated with the outer electrode. In operation, the AC power supply applies a high-frequency voltage having a frequency of not less than 1 MHz to the actuator to deform the actuator in a direction from the inner electrode toward the outer electrode in the cross section. The AC power supply stops the application of the high-frequency voltage to the actuator to return the actuator to the original position thereof.

The present invention provides a novel actuator device and a method for driving the same.

### BRIEF DESCRIPTION OF THE DRAWINGS

FIG. 1A shows a schematic view of an actuator device according to an embodiment.

FIG. 1B shows a schematic view of an actuator which has been deformed.

FIG. 2A shows a cross-sectional view of a flexible tube.

FIG. 2B shows another cross-sectional view of the flexible tube.

FIG. 2C shows still another cross-sectional view of the flexible tube.

FIG. 2D shows a cross-sectional view of the flexible tube which is not capable of being deformed.

FIG. 2E shows another cross-sectional view of the flexible tube which is not capable of being deformed.

FIG. 2F shows a cross-sectional view of the flexible tube comprising a plurality of outer electrodes.

FIG. 3A shows a schematic view of one step included in a method for fabricating the actuator.

FIG. 3B shows a schematic view of one step, subsequent to FIG. 3A, included in the method for fabricating the actuator.

FIG. 3C shows a schematic view of one step, subsequent to FIG. 3B, included in the method for fabricating the actuator.

FIG. 4 is a graph showing a relation between time and a voltage in a method for driving the actuator device with a high-frequency voltage.

FIG. 5 is a graph showing a relation between time and a voltage in a method for driving the actuator device with a low-frequency voltage.

FIG. 6 shows a schematic view of a Sawyer-Tower circuit.

FIG. 7 shows a schematic view of the actuator for defining a deformation amount.

FIG. 8 shows a schematic view of a melt-spinning method.

FIG. 9 shows a graph showing a hysteresis measurement result of an electric field—an polarization amount of the actuator according to the inventive example 1 (namely, a result of a D-E hysteresis loop measurement).

### DETAILED DESCRIPTION OF THE EMBODIMENT

Hereinafter, the embodiment of the present invention will be described with reference to the drawings.

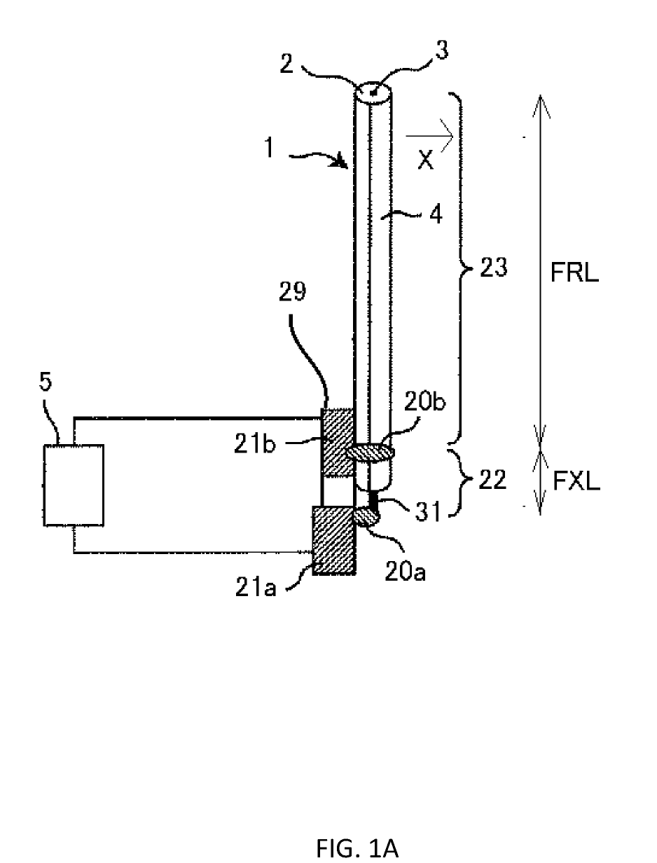

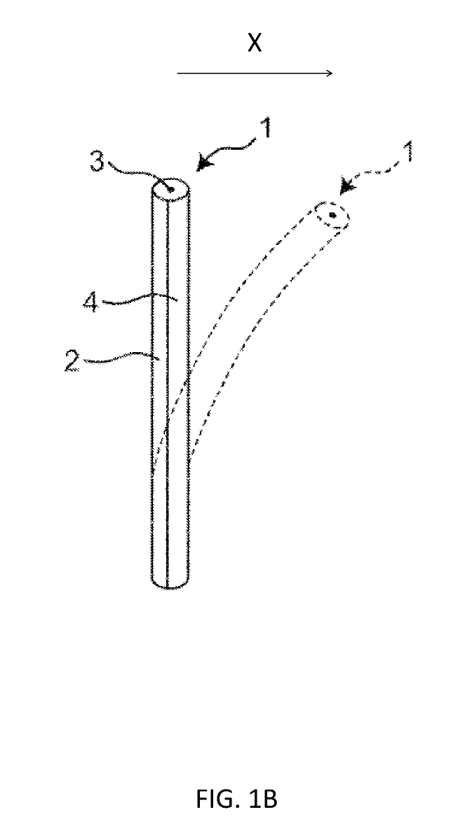

FIG. 1A shows a schematic view of an actuator device according to an embodiment. As shown in FIG. 1A, the actuator device according to the embodiment comprises an actuator 1 and an AC power supply 5. A high-frequency voltage is applied to the actuator 1 with the AC power supply 5.

(Actuator 1)

The actuator 1 comprises a flexible tube 2, an inner electrode 3 and an outer electrode 4. The flexible tube 2 is formed of a polymer, as described later in more detail. The flexible tube 2 is hollow and has an inner periphery and an outer periphery. As shown in FIG. 1A, it is desirable that the inner electrode 3 is formed along a longitudinal direction of the flexible tube 2 (namely, a vertical direction in FIG. 1A). Similarly, it is desirable that the outer electrode 4 is also formed along the longitudinal direction of the flexible tube 2. As will be described later in more detail, the outer electrode 4 coats a right-side outer periphery of the flexible tube 2 in FIG. 1A. The high-frequency voltage is applied to the actuator 1 with the AC power supply 5 to deform the actuator 1, as shown in FIG. 1B.

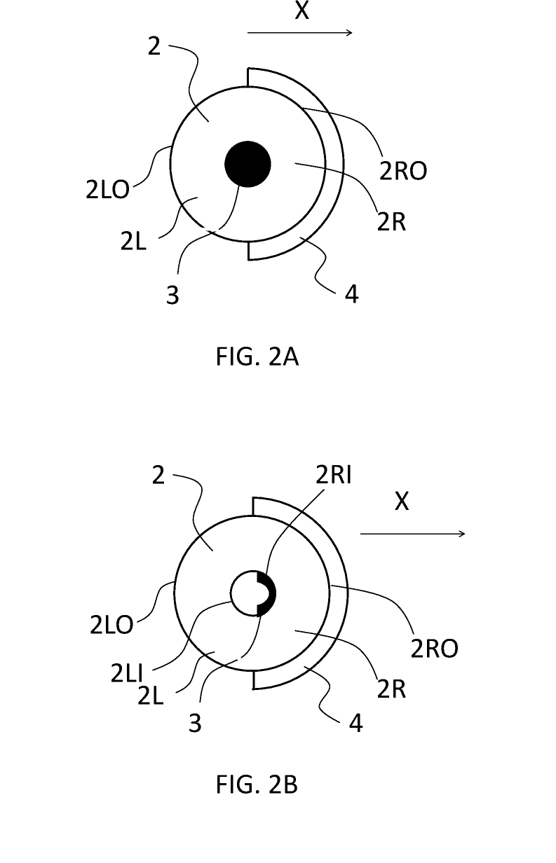

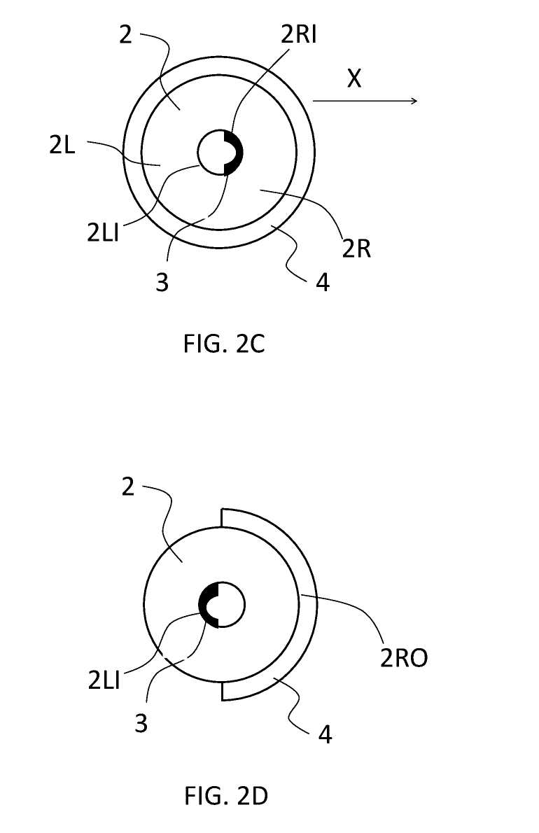

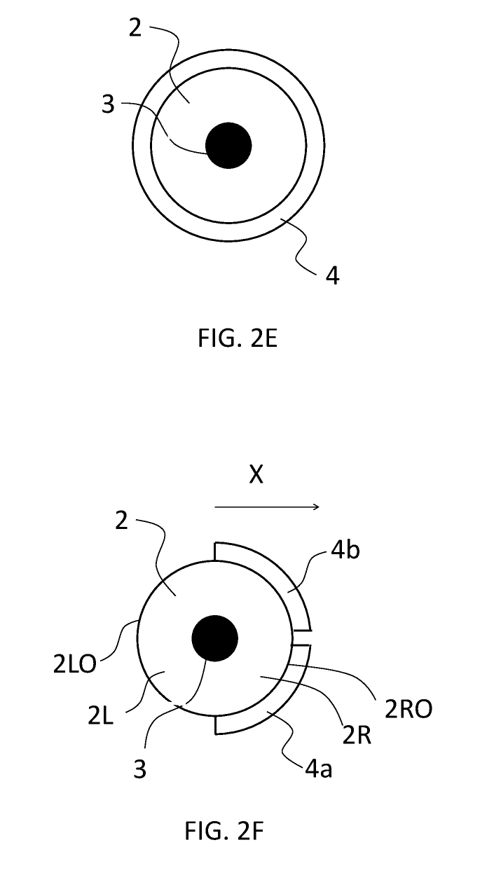

FIG. 2A shows a cross-sectional view of the flexible tube 2. In more detail, FIG. 2A shows a cross-sectional view perpendicular to the longitudinal direction of the flexible tube 2. The term “cross section” used in the instant specification means a cross section perpendicular to the longitudinal direction of the flexible tube 2.

As shown in FIG. 2A, the inner electrode 3 may be in contact with whole circumference of the inner periphery of the flexible tube 2 so as to fill the inside of the flexible tube 2. The inner electrode 3 may be referred to as a core electrode. The outer electrode 4 coats a right-side part 2RO of the outer periphery of the flexible tube 2. On the other hand, a left-side part 2LO of the outer periphery of the flexible tube 2 is exposed. As will be described later in more detail, when an AC voltage is applied to the actuator 1 with the AC power supply 5, an electric field is applied to the polymer located between the inner electrode 3 and the outer electrode 4 (namely, a right half 2R of the flexible tube 2 in FIG. 2A). On the other hand, an electric field is not applied to a left half 2L of the flexible tube 2. As a result, the actuator 1 is deformed in a direction from the inner electrode 3 toward to the outer electrode 4 (i.e., a direction of the arrow X included in FIG. 2A). In FIG. 2A, the inner electrode 3 may be hollow.

FIG. 2B shows another cross-sectional view of the flexible tube 2. As shown in FIG. 2B, the inside of the flexible tube 2 does not have to be filled with the inner electrode 3. Besides, the inner electrode 3 does not have to be in contact with the whole circumference of the inner periphery of flexible tube 2. As shown in FIG. 2B, the inner electrode 3 may be in contact with a part of the inner periphery of the flexible tube 2. In FIG. 2B, the inner electrode 3 is in contact with a right-side part 2RI of the inner periphery of the flexible tube 2. On the other hand, the inner electrode 3 is not in contact with a left-side part 2LI of the inner periphery of the flexible tube 2. The outer electrode 4 coats the right-side part 2RO of the outer periphery of the flexible tube 2. On the other hand, the left-side part 2LO of the outer periphery of the flexible tube 2 is exposed. Also in a case shown in FIG. 2B, when an AC voltage is applied to the actuator 1 with the AC power supply 5, an electric field is applied to a part of the polymer (i.e., the right half 2R of the flexible tube 2) located between the inner electrode 3 and the outer electrode 4. On the other hand, an electric field is not applied to the left half 2L of the flexible tube 2. As a result, the actuator 1 is deformed in the direction of the arrow X. The present inventors believe that a deformation amount is more in a case where the flexible tube 2 is hollow (for example, see FIG. 2B) than in a case where the inside of the flexible tube 2 is filled with the inner electrode 3 (for example, see FIG. 2A).

FIG. 2C shows still another cross-sectional view of the flexible tube 2. As shown in FIG. 2C, the inner electrode 3 is in contact with a part of the inner periphery of the flexible tube 2 (i.e., the right-side part 2RI). Furthermore, the outer electrode 4 coats the whole circumference of the outer periphery of the flexible tube 2. Also in a case shown in FIG. 2C, when an AC voltage is applied to the actuator 1 with the AC power supply 5, an electric field is applied to the part of the polymer (i.e., the right half 2R of the flexible tube 2) located between the inner electrode 3 and the outer electrode 4. On the other hand, an electric field is not applied to the left half 2L of the flexible tube 2. As a result, the actuator 1 is deformed in the direction of the arrow X.

However, in case shown in FIG. 2D, the actuator 1 fails to be deformed. In FIG. 2D, the inner electrode 3 is in contact with the left-side part 2LI of the inner periphery of the flexible tube 2, whereas the outer electrode 4 is in contact with the right-side part 2RO of the outer periphery of the flexible tube 2. In FIG. 2D, even when an AC voltage is applied to the actuator 1 with the AC power supply 5, the actuator 1 fails to be deformed, since an electric field is seldom applied to the flexible tube 2.

Also in case where in FIG. 2E, the actuator 1 fails to be deformed, since an electric field is applied circularly-symmetrically to the whole of the polymer located between the inner electrode 3 and the outer electrode 4.

As is clear from FIG. 2A, FIG. 2B, FIG. 2C, FIG. 2D, and FIG. 2E, either the following requirement (I) or (II) is required to be satisfied.

Requirement (I):
(Ia) in the cross section, the inner electrode 3 is in contact with at least a part of the inner periphery of the flexible tube 2 (e.g., the right-side part 2RI),
(Ib) in the cross section, a part of the outer periphery of the flexible tube 2 (e.g., the right-side part 2RO) is coated with the outer electrode 4, whereas all of the outer periphery of the flexible tube 2 is not coated with the outer electrode 4; and
(Ic) in the cross section, the outer electrode 4 faces at least a part of the inner periphery of the flexible tube 2 which is in contact with the inner electrode 3 (e.g., the right-side part 2RI in FIG. 2B, the inner electrode 3 itself in FIG. 2A) in such a manner that a part of the flexible tube 2 (e.g., the right-side part 2R of the flexible tube 2) is interposed therebetween (See FIG. 2A and FIG. 2B),

Requirement (II)
(IIa) in the cross section, the inner electrode 3 is in contact with a part of the inner periphery of the flexible tube 2 (e.g., the right-side part 2RI), whereas the inner electrode 3 is not in contact with all of the inter periphery of the flexible tube 2; and
(IIb) in the cross section, the whole circumference of the outer periphery of the flexible tube 2 is coated with the outer electrode 4 (See FIG. 2C).

In the cross section, a ratio of the length of the part of the outer periphery of the flexible tube 2 coated with the outer electrode 4 (e.g., the right-side part 2RO) to the length of the part of the outer periphery of the flexible tube 2 which has not coated with the outer electrode 4 (e.g., the left-side part 2LO) may be not less than one-third and not more than 3. In other words, the value of (the length of the right-side part 2RO)/((the length of the right-side part 2RO)+(the length of the left-side part 2LO)) may be not less than 25% and not more than 75%. In the instant specification, the value is referred to as a coating ratio. Desirably, the value (i.e., the coating ratio) is approximately 50%.

As shown in FIG. 2F, in the cross section, the outer electrode 4 may include a first outer electrode portion 4a and a second outer electrode portion 4b. Each of the first outer electrode portion 4a and the second outer electrode portion 4b coats the part of the outer periphery of the flexible tube 2. It is desirable that each of the first outer electrode portion 4a and the second outer electrode portion 4b is formed along the longitudinal direction of the flexible tube 2. However, the first outer electrode portion 4a and the second outer electrode portion 4b must not be disposed circularly-symmetrically in the cross section. In this case, similarly to the case shown in FIG. 2E, the actuator 1 fails to be deformed.

Although not shown, the inner electrode 3 may also include a first inner electrode portion and a second inner electrode portion. Each of the first inner electrode portion and the second inner electrode portion is in contact with the part of the inner periphery of the flexible tube 2. It is desirable that each of the first inner electrode portion and the second inner electrode portion is formed along the longitudinal direction of the flexible tube 2.

The cross section of the flexible tube 2 may be circular; however, the shape of the cross section of the flexible tube 2 is not limited, as long as the actuator 1 is deformed by the application of the AC voltage with the AC power supply 5. An example of the shape of the cross section of the flexible tube 2 is a circle, an ellipse, or a polygon.

The flexible tube 2 is formed of a polymer. Desirably, the flexible tube 2 is formed of a polymer represented by the following chemical formula (I) or a copolymer thereof:

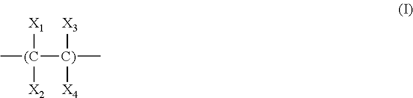

where

X₁ is a halogen atom, and

X₂, X₃, and X₄ are, each independently, one kind selected from the group consisting of a hydrogen atom and a halogen atom.

In the chemical formula (I), it is desirable that the halogen atom is a fluorine atom.

More desirably, the flexible tube 2 is formed of a copolymer represented by the following chemical formula (II):

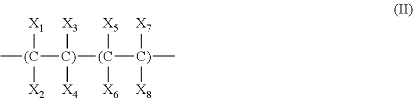

where

X₁ is a halogen atom, and

X₂-X₈ are, each independently, one kind selected from the group consisting of a hydrogen atom and a halogen atom.

Also in the chemical formula (II), it is desirable that the halogen atom is a fluorine atom.

As one example, X₁, X₂, X₅, X₆, and X₇ are fluorine atoms and X₃, X₄, and X₈ are hydrogen. In other words, the flexible tube 2 may be formed of a copolymer of vinylidene fluoride and trifluoroethylene (hereinafter, referred to as “P(VDF/TrFE)” copolymer).

As described above, it is desirable that the flexible tube 2 is formed of a piezoelectric polymer. When the flexible tube 2 is formed of a piezoelectric polymer, it is desirable that the piezoelectric polymer is subjected to polarization treatment. Due to the polarization treatment, the polarization of the piezoelectric polymer is oriented in a direction from the inner electrode 3 toward the outer electrode 4. For the polarization treatment, a Sawyer-Tower circuit may be used. In addition, the polarization treatment may be omitted.

(Fabrication Method of Actuator 1)

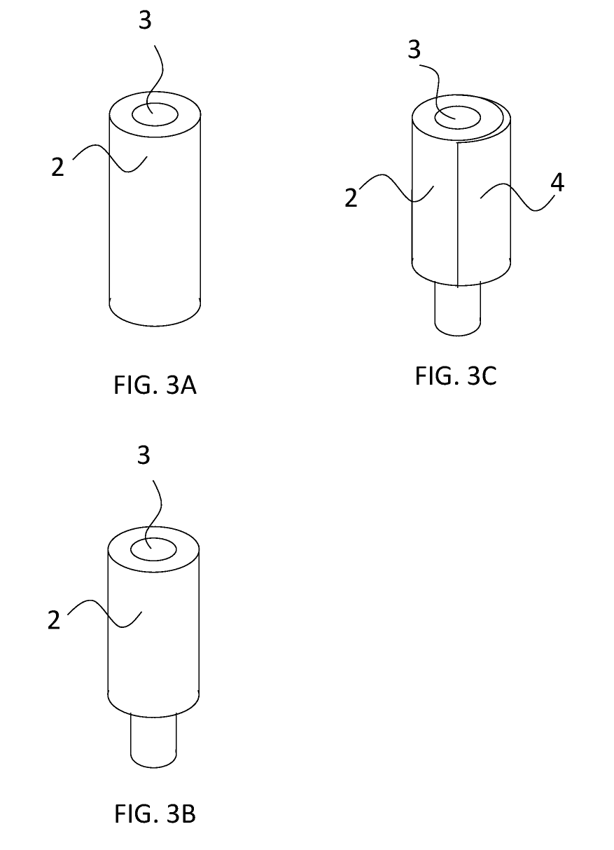

The actuator 1 may be fabricated as below. As shown in FIG. 3A, a polymer is formed on the outer periphery of the inner electrode 3 formed of a linear metal wire. In this way, the flexible tube 2 is formed on the outer periphery of the inner electrode 3. Then, as shown in FIG. 3B, one end of the flexible tube 2 (the bottom end, in FIG. 3B) is removed to expose one end 31 of the inner electrode 3. Then, as shown in FIG. 3C, a part of the outer periphery of the flexible tube 2 (the right half part, in FIG. 3C) is coated by a sputtering method with a metal to form the outer electrode 4. In this way, the actuator 1 is fabricated. For more detail, see examples which will be described later. A skilled person who has read the examples can fabricate the actuator 1 according to the embodiment easily. The actuator 1 may be subjected to the polarization treatment, if necessary.

As shown in FIG. 1A, the exposed one end of the inner electrode 3 and a part of the outer electrode 4 are fixed on a substrate 29 comprising metal tapes 21a and 21b on the surface thereof with conductive pastes 21a and 21b. The AC power supply 5 is connected electrically to the metal tapes 21a and 21b. In this way, the actuator device according to the embodiment is provided.

As shown in FIG. 1A, a part of the actuator 1 which is fixed to the substrate 29 is referred to as a fixed end part 22. The fixed end part 22 has a length FXL (hereinafter, referred to as a fixed length FXL). The other part of the actuator 1 is referred to as a free part 23. The free part 23 has a length FRL (hereinafter, referred to as a free length FRL).

(AC Power Supply 5)

The high-frequency voltage having a frequency of not less than 1 MHz is applied to the actuator 1 with the AC power supply 5. In the instant specification, “high-frequency voltage” means an AC voltage having a frequency of not less than 1 MHz. On the other hand, in the instant specification, “low-frequency voltage” means an AC voltage having a frequency of less than 1,000 KHz. Desirably, the AC voltage has a peak-to-peak voltage of not less than 1 volt and not more than 100 volts, more desirably, not less than 3 volts and not more than 30 volts, still more desirably, not less than 4 volts and not more than 10 volts. A user of the actuator device connects the actuator 1 to the AC power supply 5 electrically to prepare the actuator device. Alternatively, the user of the actuator device purchases an actuator device comprising the actuator 1 and the AC power supply 5 to prepare the actuator device.

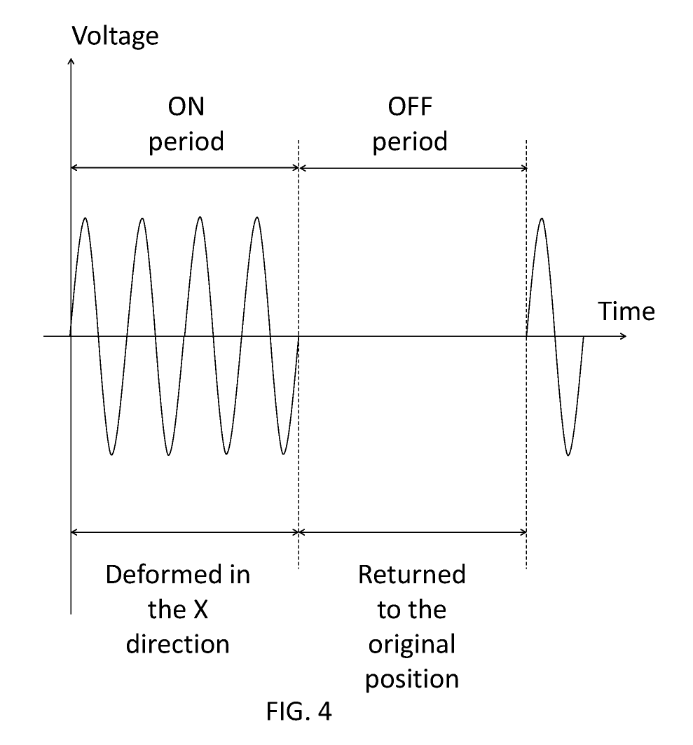

When the high-frequency voltage is applied to the actuator 1, as shown in FIG. 1B, the free part 23 of the actuator 1 is deformed to the X direction. As shown in FIG. 4, while the high-frequency voltage is applied to the actuator 1, the deformation of the actuator 1 is maintained, although a plus voltage and a minus voltage are applied alternately to the actuator 1 at a high frequency. In other words, while the high-frequency voltage is applied to the actuator 1, the free part 23 does not return to its original position and is not deformed to a direction opposite to the X direction.

On the other hand, when the application of the voltage to the actuator 1 is stopped, the actuator 1 returns to its original position.

Hereinafter, in the instant specification, the period during which the voltage is applied to the actuator 1 is defined as “ON period”. On the other hand, in the instant specification, the period during which the voltage is not applied to the actuator 1, namely, the period during which the application of the voltage to the actuator 1 is stopped, is defined as “OFF period”.

As one example, it is desirable that the following mathematical formula (I) is satisfied between the ON period and the OFF period.

6 Hz≤1/(ON period+OFF period)≤26 Hz (I)

The present inventors believe that the actuator 1 has a resonance frequency of not less than 6 Hz and not more than 26 Hz. For this reason, the deformation amount of the actuator 1 is remarkable at the resonance frequency. See Table 3, which will be described later. The AC power supply 5 can apply a high-frequency voltage to the actuator 1 intermittently so as to satisfy the mathematical formula (I).

The duty ratio (i.e., (length of ON period)/((length of ON period)+(length of OFF period))) is not limited. As one example, the duty ratio is 0.5.

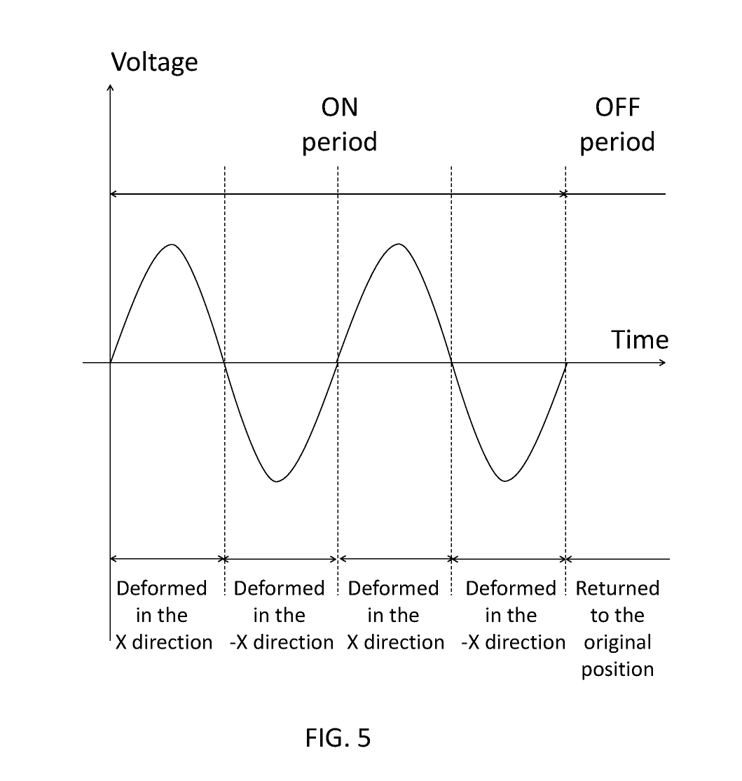

As shown in FIG. 5, in case where a voltage having a frequency of less than 1,000 KHz (namely, a low-frequency voltage) is applied to the actuator 1, the free part 23 of the actuator 1 is deformed during the ON period in the X-direction (referred to as “+X direction” in the present paragraph and FIG. 5) and in the reverse direction of the X-direction (referred to as “−X direction” in the present paragraph and FIG. 5) in synchronization with a plus phase (namely, a period during which a plus voltage is applied) and a minus phase (namely, a period during which a minus voltage is applied), respectively. At a moment when no voltage is applied (namely, at a moment when a voltage of 0 volts is applied to the actuator 1), the free part 23 of the actuator 1 is returned to its original position. The spirit of the present invention does not include the drive of the actuator 1 with a low-frequency voltage.

### EXAMPLES

### Inventive Example 1

(Fabrication of the Actuator 1)

The actuator 1 according to the inventive example 1 was fabricated as below.

First, an inner electrode 3 formed of a copper wire having a diameter of 30 micrometers was washed with acetone. Then, the lateral surface of the inner electrode 3 was irradiated with ultraviolet light for five minutes.

Apart from this, a copolymer of vinylidene fluoride and trifluoroethylene (hereinafter, referred to as “P(VDF/TrFE) copolymer”, purchased from Kureha Corporation, trade name “KFW#2200”) was dissolved in diethyl carbonate maintained at 90 degrees Celsius. In this way, a dip coating solution was provided. A copolymerization ratio (ratio by weight) of vinylidene fluoride and trifluoroethylene in the P(VDF/TrFE) copolymer was 75:25.

Then, the copper wire was immersed in the dip coating solution to coat the lateral surface of the inner electrode 3 with the P(VDF/TrFE) copolymer. In this way, as shown in FIG. 3A, the lateral surface of the inner electrode 3 was coated with a flexible tube 2 formed of the P(VDF/TrFE) copolymer. The flexible tube 2 had a thickness of approximately 20 micrometers.

The flexible tube 2 was cut together with the inner electrode 3 so as to have a length of 30 millimeters.

One end of the cut flexible tube 2 was immersed in diethyl carbonate maintained at 90 degrees Celsius for three minutes to remove a bottom part of the P(VDF/TrFE) copolymer which coated the one end of the cut inner electrode 3. In this way, the one end of the cut inner electrode 3 was exposed, as shown in FIG. 3B. The exposed part of the inner electrode 3 had a length of 2 millimeters. The exposed part of the inner electrode 3 was masked with a polyimide film (not illustrated).

Aluminum was evaporated by a sputtering method to a half of the outer periphery of the flexible tube 2. In this way, an outer electrode 4 was formed of aluminum, as shown in FIG. 3C. The outer electrode 4 had a thickness of approximately 100 nanometers. The outer electrode 4 was formed along a longitudinal direction of the flexible tube 2. Roughly half of the outer periphery of the flexible tube 2 was coated with the outer electrode 4. In other words, roughly half of the outer periphery of the flexible tube 2 was coated with the outer electrode 4, whereas the other half of the outer periphery of the flexible tube 2 was not coated with the outer electrode 4 to be exposed. Then, the polyimide film was removed. In this way, the actuator 1 according to the inventive example 1 was provided. In other words, the inner electrode 3 and the outer electrode 4 were formed on the inner periphery and the outer periphery of the flexible tube 2, respectively.

(Adhesion of the Actuator 1 to the Substrate 29)

As shown in FIG. 1, the actuator 1 according to the inventive example 1 was attached to the substrate 29 as below. The substrate 29 had a first copper tape 21a and a second cupper tape 21b on the surface thereof. The first copper tape 21a was insulated electrically from the second cupper tape 21b. The exposed part of the inner electrode 3 and the part of the bottom end of the outer electrode 4 were bound to the first copper tape 21a and the second cupper tape 21b, respectively, with conductive pastes 20a and 21b. In this way, the bottom end of the actuator 1 (i.e., the exposed part of inner electrode 3) served as the fixed end part 22. On the other hand, a part other than the bottom end of the actuator 1 served as the free part 23.

(Polarization Treatment)

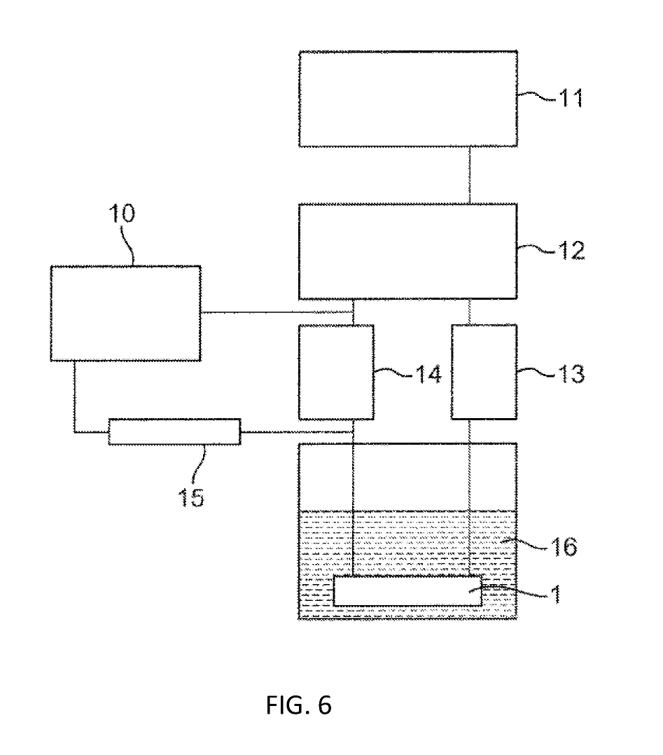

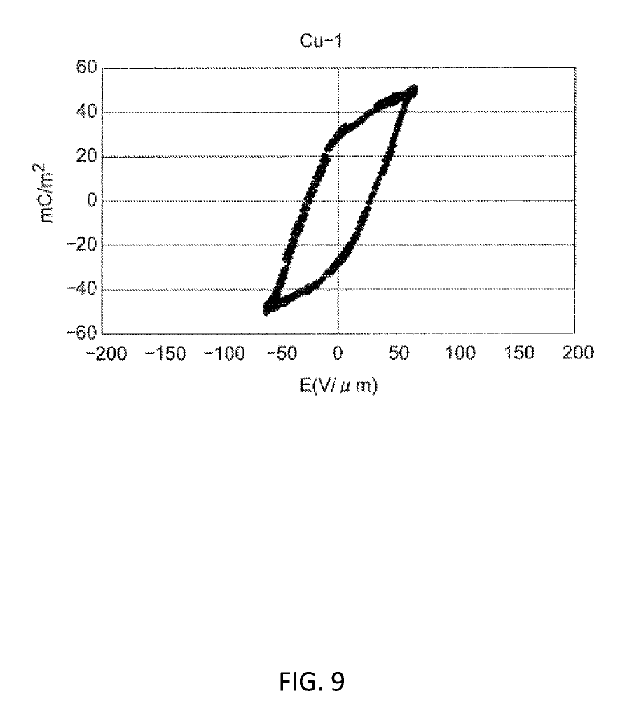

As shown in FIG. 6, the actuator 1 according to the inventive example 1 was subjected to the polarization treatment. FIG. 6 shows a schematic view of a Sawyer-Tower circuit used for the polarization treatment. As shown in FIG. 6, the Sawyer-Tower circuit used in the inventive example 1 comprised an oscilloscope 10, an AC voltage power source 11 (purchased from Agilent Technologies, trade name: 33250A), an AC/DC amplifier 12 (purchased from NF Corporation, trade name: HVA4322), a high resistor 13 (0.1 mega ohm-10 giga ohm, purchased from Japan Finechem Company, Inc., trade name: RH6HVS), a capacitor 14 (2.6 microfarads at 1 KHz), and a probe 15 (purchased from Tektronix, Inc., trade name: P3000). The actuator 1 according to the inventive example 1 was immersed in oil 16. FIG. 9 is a graph showing a hysteresis measurement result of an electric field—a polarization amount of the actuator 1 according to the inventive example 1 (namely, a result of D-E hysteresis loop measurement). The actuator 1 according to the inventive example 1 had a residual polarization of 60 mC/m².

(High-Frequency Drive)

As shown in FIG. 1, an AC power supply 5 (purchased from Agilent Technologies, trade name: 33250A) was electrically connected to the actuator 1 according to the inventive example 1. The free length FRL was 25 millimeters. The fixed length FXL was 5 millimeters. A high-frequency voltage having a peak-to-peak voltage of 10 volts was applied to the actuator 1 according to the inventive example 1 with the AC power supply 5. The high-frequency voltage was an AC voltage of a sine wave. The frequency of the high-frequency voltage was 1 MHz.

As shown in FIG. 4, the high-frequency voltage was applied to the actuator 1 during the ON period of 0.05 seconds, whereas the high-frequency voltage was not applied to the actuator 1 during the OFF period of 0.05 seconds. The ON period and the OFF period were alternately repeated. As shown in FIG. 4, the free part 23 of the actuator 1 was deformed in the X direction during the ON period, whereas the free part 23 of the actuator 1 was not deformed and was returned to its original position during the OFF period. The ON-OFF frequency was 10 Hz (=1/((ON period: 0.05 seconds)+(OFF period: 0.05 seconds))). The ON-OFF duty ratio was 0.5 (=(ON period: 0.05 seconds)/((ON period: 0.05 seconds)+(OFF period: 0.05 seconds))).

In more detail, as shown in FIG. 4, unlike a case of a low-frequency drive which will be described later, although a plus voltage and a minus voltage are applied to the actuator 1 alternately at a high frequency during the ON period, the deformation of the free part 23 of the actuator 1 to the X direction was maintained. Furthermore, during the ON period, the free part 23 of the actuator 1 was not returned to its original position and was not deformed to the reverse direction of the X direction.

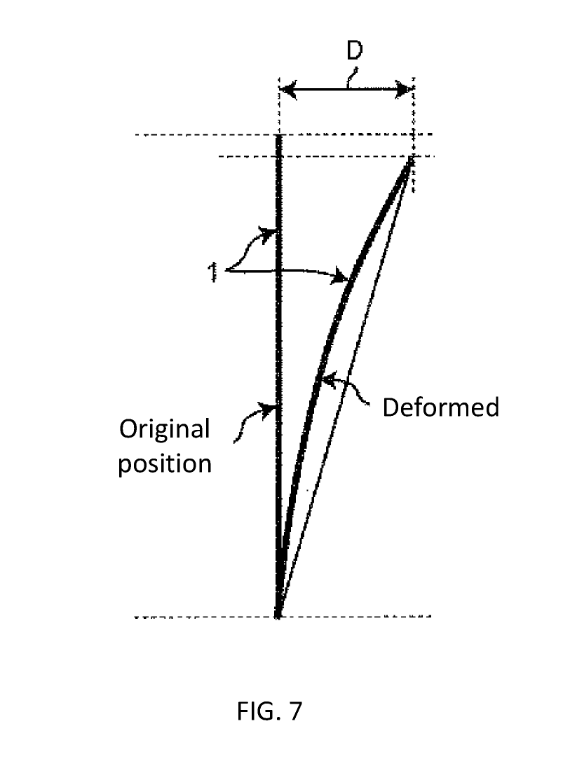

As just described, during the ON period, the free part 23 of the actuator 1 was synchronized with neither the plus phase (namely, the period during which the plus voltage was applied) nor the minus phase (namely, the period during which the minus voltage was applied) of the high-frequency voltage applied to the actuator 1. The free part 23 of the actuator 1 was not returned to its original position. The free part 23 of the actuator 1 was not deformed in the reverse direction of the X direction. During the ON period, as shown in FIG. 7, the free part 23 of the actuator 1 remained deformed in the X direction. In the instant specification, such a movement of the actuator 1 (i.e., deformation) is referred to as “high-frequency driving”.

Needless to say, the fixed end part 22 was not deformed during both the ON period and the OFF period.

The deformation amount D of the free part 23 was measured. FIG. 7 shows a schematic view of the measurement of the deformation amount D of the free part 23. In the instant specification, as shown in FIG. 7, the deformation amount D is defined as a distance between the position of the free part 23 during the OFF period and the position of the free part 23 during the ON period.

(Measurement of Deformation Amount D with Change of Frequency)

In the inventive example 1, the frequency of the high-frequency voltage was changed as shown in the following Table 1. The deformation amount D in each frequency was measured.

TABLE 1
Peak-to-peak voltage: 10 volts
ON-OFF frequency: 22 Hz

| Frequency of the high- | |
|---|---|
| frequency voltage | Deformation amount D |
| (MHz) | (millimeters) |
| 1 | 0.009 |
| 10 | 0.05 |
| 20 | 0.1125 |
| 25 | 0.19375 |
| 30 | 0.425 |
| 40 | 2.65 |
| 50 | 2.65 |
| 60 | 2.65 |
| 70 | 2.25 |
| 80 | 1.675 |

As is clear from Table 1, when the high-frequency voltage has a frequency of not less than 1 MHz, the actuator 1 is deformed. In view of the deformation amount D, it is desirable that the high-frequency voltage has a frequency of not less than 40 MHz and not more than 70 MHz. More desirably, the high-frequency voltage has a frequency of not less than 40 MHz and not more than 60 MHz. One example of the upper limit of the high-frequency voltage is 80 MHz.

(Measurement of Deformation Amount D with Change of Peak-to-Peak Voltage)

Next, the peak-to-peak voltage was changed as shown in the following Table 2. The deformation amount D in each peak-to-peak voltage was measured. The frequency of the high-frequency voltage was 40 MHz.

TABLE 2
Frequency of high-frequency voltage: 40 MHz
ON-OFF frequency: 10 Hz

| Peak-to-peak voltage | Deformation amount D |
|---|---|
| (volts) | (millimeters) |
| 4 | 0.075 |
| 5 | 0.2125 |
| 6 | 0.4 |
| 7 | 0.825 |
| 8 | 1.125 |
| 9 | 1.425 |

As is clear from Table 2, the deformation amount D is increased with an increase in the peak-to-peak voltage.

(Measurement of Deformation Amount D with Change of ON-OFF Frequency)

Furthermore, the ON-OFF frequency was changed as shown in the following Table 3. The deformation amount D in each ON-OFF frequency was measured. The frequency of the high-frequency voltage was 25 MHz. The peak-to-peak voltage was 10 volts.

TABLE 3
Frequency of high-frequency voltage: 25 MHz
Peak-to-peak voltage: 10 volts

| ON-OFF frequency | Deformation amount D |
|---|---|
| (Hz) | (millimeters) |
| 6 | 0.00389 |
| 10 | 0.00588 |
| 14 | 0.00586 |
| 18 | 0.01278 |
| 22 | 0.19375 |
| 23 | 0.0369 |
| 26 | 0.0078 |

As is clear from Table 3, when the ON-OFF frequency is 22 Hz, the deformation amount D is remarkable. For this reason, the present inventors believe that the actuator 1 according to the inventive example 1 had a resonance frequency of 22 Hz.

In the instant specification, the ON-OFF frequency is defined on the basis of the following mathematical formula (II):

(ON-OFF frequency)=1/((time of the ON period)+(time of the OFF period)) (II)

“The ON-OFF frequency” may be referred to as “intermittent frequency”.

(Reference: Low-Frequency Drive)

A low-frequency voltage having a peak-to-peak voltage of 60 volts was applied to the actuator 1 according to the inventive example 1 with the AC power supply 5. The low-frequency voltage was an AC voltage of a sine wave. The frequency of the low-frequency voltage was 1 Hz-30 Hz.

As shown in FIG. 5, unlike a case of the high-frequency drive, in the low-frequency drive, the free part 23 of the actuator 1 was deformed during the ON period in the X direction and the reverse direction of the X direction respectively in synchronization with the plus phase (namely, the period during which the plus voltage is applied) and the minus phase (namely, the period during which the minus voltage is applied). At a moment when no voltage was applied (namely, at a moment when a voltage of 0 volts was applied to the actuator 1), the free part 23 of the actuator 1 was returned to its original position. When the frequency of the low-frequency voltage was 22 Hz, the actuator 1 according to the inventive example 1 had the largest deformation amount D of 7.5 micrometers.

### Inventive Example 2

In the inventive example 2, the actuator 1 was fabricated similarly to the inventive example 1, except that the lateral surface of the inner electrode 3 was coated with the flexible tube 2 formed of a P(VDF/TrFE) copolymer by a melt spinning method in place of the dip coating method.

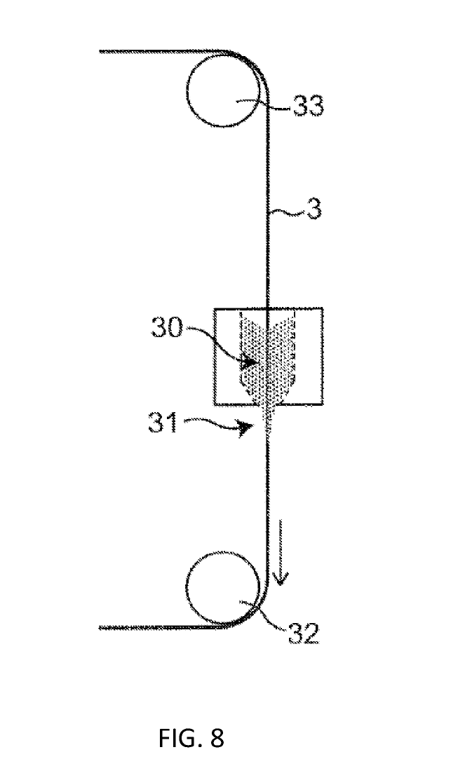

FIG. 8 shows a schematic view of a melt spinning method. In the inventive example 2, the inner electrode 3 formed of a copper wire was guided by a first pulley 33 to and was put into a melting furnace 30. In the inside of the melting furnace 30, the lateral surface of the inner electrode 3 was coated with the flexible tube 2 formed of the P(VDF/TrFE) copolymer. In the inside of the melting furnace 30, the flexible tube 2 was heated to 270 degrees Celsius. The inner electrode 3 formed of the copper wire coated in this way was extruded out of the melting furnace 30 through a die 31 having an inner diameter of 0.5 millimeters. The inner electrode 3 extruded in this way was guided by a second pulley 32 and was reeled off at a rate of 2 rpm/minute.

The deformation amount D of the actuator 1 according to the inventive example 2 was measured under a condition where the frequency of the high-frequency voltage was 25 MHz, the peak-to-peak voltage was 10 volts, and the ON-OFF frequency was 1 Hz. As a result, the actuator 1 according to the inventive example 2 had a deformation amount D of 75 micrometers.

### Inventive Example 3

In the inventive example 3, the actuator 1 was fabricated similarly to the inventive example 1 except for the following matters (I)-(III).

(I) The free length FRL was 37 millimeters and the fixed length FXL was 5 millimeters.

(II) The inner electrode 3 formed of a piano wire (i.e., carbon steel) having a diameter of 20 micrometers was used in place of the inner electrode 3 formed of the copper wire.

(III) The polarization treatment was not conducted.

The deformation amount D of the actuator 1 according to the inventive example 3 was measured under a condition where the frequency of the high-frequency voltage was 25 MHz, the peak-to-peak voltage was 10 volts, and the ON-OFF frequency was 1 Hz. As a result, the actuator 1 according to the inventive example 3 had a deformation amount D of 38 micrometers.

### Comparative Example 1

In the comparative example 1, the deformation amount D of the actuator 1 according to the inventive example 1 was measured under a condition where the frequency of the low-frequency voltage was 10 Hz and the peak-to-peak voltage was 60 volts. In the comparative example 1, the OFF period was absent, and the ON period was always present. As a result, in the comparative example 1, the actuator 1 had a deformation amount D of approximately 0 micrometers. In other words, in the comparative example 1, the actuator 1 did not drive.

### Comparative Example 2

In the comparative example 2, the deformation amount D of the actuator 1 according to the inventive example 2 was measured under a condition where the frequency of the low-frequency voltage was 1 Hz and the peak-to-peak voltage was 60 volts. In the comparative example 2, the OFF period was absent, and the ON period was always present. As a result, in the comparative example 2, the actuator 1 had a deformation amount D of approximately 0 micrometers. In other words, in the comparative example 2, the actuator 1 did not drive.

### Comparative Example 3

In the comparative example 3, the deformation amount D of the actuator 1 according to the inventive example 3 was measured under a condition where the frequency of the low-frequency voltage was 1 Hz and the peak-to-peak voltage was 60 volts. In the comparative example 3, the OFF period was absent, and the ON period was always present. As a result, in the comparative example 3, the actuator 1 had a deformation amount D of approximately 0 micrometers. In other words, in the comparative example 3, the actuator 1 did not drive.

### INDUSTRIAL APPLICABILITY

The actuator device according to the present invention can be used as an artificial muscle.

### REFERENTIAL SIGNS LIST

1 Actuator device
2 Flexible tube
2L Left half of flexible tube
2LI Left-side part of inner periphery of flexible tube
2LO Left-side part of outer periphery of flexible tube
2R Right half of flexible tube
2RI Right-side part of inner periphery of flexible tube
2RO Right-side part of outer periphery of flexible tube
3 Inner electrode
30 Melting furnace
31 Die
32 Second pulley
33 First pulley
4 Outer electrode
4a First outer electrode portion
4b Second outer electrode portion
5 AC power supply
10 Oscilloscope
11 AC voltage power source
12 AC/DC amplifier
13 High resistor
14 Capacitor
15 Probe
16 Oil
20a Conductive paste
20b Conductive paste
21a Metal tape
21b Metal tape
22 Fixed end part
23 Free part
29 Substrate
31 One end of Inner electrode
D Deformation amount
FRL Free Length
FXL Fixed Length

1. An actuator device, comprising:
an actuator; and
an AC power supply capable of applying a high-frequency voltage to the actuator,
wherein
the actuator comprises a flexible tube formed of a polymer, an inner electrode, and an outer electrode;
the inner electrode is in contact with at least a part of an inner periphery of the flexible tube in a cross section perpendicular to a longitudinal direction of the flexible tube;
in the cross section, a part of an outer periphery of the flexible tube is coated with the outer electrode;
in the cross section, the part of the outer periphery of the flexible tube coated with the outer electrode faces the at least the part of an inner periphery of the flexible tube which is in contact with the inner electrode so as to interpose a part of the flexible tube therebetween; and
the AC power supply, in operation,
applies the high-frequency voltage having a frequency of not less than 1 MHz to the actuator to deform the actuator in a direction from the inner electrode toward the outer electrode in the cross section, and
stops the application of the high-frequency voltage to the actuator to return the actuator to the original position thereof.

2. The actuator device according to claim 1, wherein
the inner electrode is formed along a longitudinal direction of the flexible tube.

3. The actuator device according to claim 1, wherein
the outer electrode is formed along a longitudinal direction of the flexible tube.

4. The actuator device according to claim 1, wherein
the high-frequency voltage has a frequency of not more than 100 MHz.

5. The actuator device according to claim 1, wherein
the AC power supply is capable of applying the high-frequency voltage intermittently to the actuator so as to satisfy the following mathematical formula (I):
6 Hz≤1/(ON period+OFF period)≤26 Hz (I)
where
the ON period is defined as a period during which the high-frequency voltage is applied to the actuator; and
the OFF period is defined as a period during which the high-frequency voltage is not applied to the actuator.

6. The actuator device according to claim 1, wherein
in the cross section, the inner electrode is in contact with whole circumference of the inner periphery of the flexible tube so as to fill an inside of the flexible tube.

7. The actuator device according to claim 1, wherein
a part of the outer periphery of the flexible tube which is not coated with the outer electrode is exposed.

8. The actuator device according to claim 1, wherein
the following mathematical formula (II) is satisfied:
25%≤coating ratio≤75% (II)
where
the coating ratio=(in the cross section, a length of the part of the outer periphery of the flexible tube which is coated with the outer electrode)/(in the cross section, a length of the other part of the outer periphery of the flexible tube which is not coated with the outer electrode).

9. The actuator device according to claim 1, wherein
the outer electrode comprises:
a first outer electrode portion which is formed along a longitudinal direction of the flexible tube and coats the part of the outer periphery of the flexible tube; and
a second outer electrode portion which is formed in parallel to the first outer electrode portion and coats the part of the outer periphery of the flexible tube; and
in the cross section, the first outer electrode portion and second outer electrode portion are disposed circularly-asymmetrically.

10. The actuator device according to claim 1, wherein
the inner electrode comprises:
a first inner electrode portion which is formed along a longitudinal direction of the flexible tube and coats the part of the inner periphery of the flexible tube; and
a second inner electrode portion which is formed in parallel to the first inner electrode portion and coats the part of the inner periphery of the flexible tube; and
in the cross section, the first inner electrode portion and the second inner electrode portion are disposed circularly-asymmetrically.

11. The actuator device according to claim 1, wherein
the flexible tube is formed of a polymer represented by the following chemical formula (I) or a copolymer thereof: 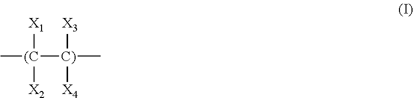
where
X₁ is a halogen atom, and
X₂, X₃, and X₄ are, each independently, one kind selected from the group consisting of a hydrogen atom and a halogen atom.

12. The actuator device according to claim 1, wherein
the flexible tube is formed of a copolymer represented by the following chemical formula (II): 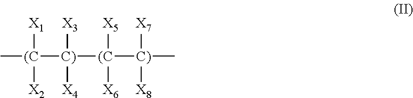
where
X₁ is a halogen atom, and
X₂-X₈ are, each independently, one kind selected from the group consisting of a hydrogen atom and a halogen atom.

13. The actuator device according to claim 12, wherein
X₁, X₂, X₅, X₆, and X₇ are fluorine atoms; and
X₃, X₄, and X₈ are hydrogen.

14. A method for driving an actuator device, the method comprising:
(a) preparing an actuator device according to claim 1; and
(b) applying a high-frequency voltage having a frequency of not less than 1 MHz between the inner electrode and the outer electrode to deform the actuator in a direction from the inter electrode toward the outer electrode in the cross section.

15. The method according to claim 14, further comprising:
(c) stopping the application of the high-frequency voltage to return the actuator to the original position thereof.

16. The method according to claim 14, wherein
the inner electrode is formed along a longitudinal direction of the flexible tube.

17. The method according to claim 14, wherein
the outer electrode is formed along a longitudinal direction of the flexible tube.

18. The method according to claim 14, wherein
the high-frequency voltage has a frequency of not more than 100 MHz.

19. The method according to claim 14, wherein
the AC power supply is capable of applying the high-frequency voltage intermittently to the actuator so as to satisfy the following mathematical formula (I):
6 Hz≤1/(ON period+OFF period)≤26 Hz (I)
where
the ON period is defined as a period during which the high-frequency voltage is applied to the actuator; and
the OFF period is defined as a period during which the high-frequency voltage is not applied to the actuator.

20. The method according to claim 14, wherein
in the cross section, the inner electrode is in contact with whole circumference of the inner periphery of the flexible tube so as to fill an inside of the flexible tube.

21. The method according to claim 14, wherein
a part of the outer periphery of the flexible tube which is not coated with the outer electrode is exposed.

22. The method according to claim 14, wherein
the following mathematical formula (II) is satisfied:
25%≤coating ratio≤75% (II)
where
the coating ratio=(in the cross section, a length of the part of the outer periphery of the flexible tube which is coated with the outer electrode)/(in the cross section, a length of the other part of the outer periphery of the flexible tube which is not coated with the outer electrode).

23. The method according to claim 14, wherein
the outer electrode comprises:
a first outer electrode portion which is formed along a longitudinal direction of the flexible tube and coats the part of the outer periphery of the flexible tube; and
a second outer electrode portion which is formed in parallel to the first outer electrode portion and coats the part of the outer periphery of the flexible tube; and
in the cross section, the first outer electrode portion and second outer electrode portion are disposed circularly-asymmetrically.

24. The method according to claim 14, wherein
the inner electrode comprises:
a first inner electrode portion which is formed along a longitudinal direction of the flexible tube and coats the part of the inner periphery of the flexible tube; and
a second inner electrode portion which is formed in parallel to the first inner electrode portion and coats the part of the inner periphery of the flexible tube; and
in the cross section, the first inner electrode portion and the second inner electrode portion are disposed circularly-asymmetrically.

25. The method according to claim 14, wherein
the flexible tube is formed of a polymer represented by the following chemical formula (I) or a copolymer thereof: 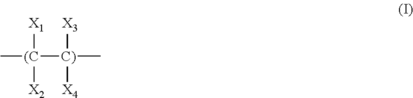
where
X₁ is a halogen atom, and
X₂, X₃, and X₄ are, each independently, one kind selected from the group consisting of a hydrogen atom and a halogen atom.

26. The method according to claim 14, wherein
the flexible tube is formed of a copolymer represented by the following chemical formula (II): 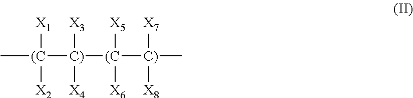
where
X₁ is a halogen atom, and
X₂-X₈ are, each independently, one kind selected from the group consisting of a hydrogen atom and a halogen atom.

27. The method according to claim 26, wherein
X₁, X₂, X₅, X₆, and X₇ are fluorine atoms; and
X₃, X₄, and X₈ are hydrogen.
